(19) United States
(12) Patent Application Publication
(10) Pub. No.: US 2015/0097270 A1
(43) Pub. Date: Apr. 9, 2015

(54) FINFET WITH RELAXED SILICON-GERMANIUM FINS

(71) Applicant: International Business Machines Corporation, Armonk, NY (US)

(72) Inventors: Stephen W. Bedell, Wappingers Falls, NY (US); Dominic J. Schepis, Wappingers Falls, NY (US); Matthew W. Stoker, Poughkeepsie, NY (US)

(73) Assignee: International Business Machines Corporation, Armonk, NY (US)

(21) Appl. No.: 14/047,090

(22) Filed: Oct. 7, 2013

(51) Int. Cl. H01L 27/092; H01L 29/161; H01L 21/8238

(52) U.S. Cl. CPC H01L 27/0924; H01L 21/823821; H01L 29/161
USPC 257/618; 438/479

(57) ABSTRACT

A method of forming a semiconductor structure includes forming a first fin in a p-FET device region of a semiconductor substrate and a second fin in an n-FET device region of the semiconductor substrate substantially parallel to the first fin. The first fin and the second fin each comprise a strained semiconductor material. Next, the second fin is amorphized to form a relaxed fin by implanting ions into the second fin while protecting the first fin.

### BACKGROUND

The present invention generally relates to semiconductor devices, and more particularly to field effect transistor (FET) devices including FinFET structures, and a method for making the same.

Complementary Metal-oxide-semiconductor (CMOS) technology is commonly used for fabricating field effect transistors (FETs) as part of advanced integrated circuits (IC), such as CPUs, memory, storage devices, and the like. At the core of a planar FET is a channel region formed in an n-doped or p-doped semiconductor substrate on which a gate structure is formed. Depending whether the on-state current is carried by electrons or holes, the FET can become an n-FET device or a p-FET device. The overall fabrication process may include forming a gate structure over a channel region connecting a source region and a drain region within the substrate on opposite sides of the gate, typically with some vertical overlap between the gate and the source and drain region.

As integrated circuits continue to scale downward in size, fin field effect transistors (FinFETs) or tri-gate structures are becoming more widely used, primarily because FinFETs can offer better performance than planar FETs at the same power budget. FinFETs are three dimensional (3-D), fully depleted metal-oxide semiconductor field effect transistor (MOSFET) devices having a fin structure formed from the semiconductor substrate material. The fins extend between the device source and drain enfolding the channel region forming the bulk of the semiconductor device. The gate structure is located over the fins covering the channel region. Such architecture may allow for a more precise control of the conducting channel by the gate, and may reduce the amount of current leakage when the device is in an off-state.

Existing CMOS high-k devices rely on n-FET and p-FET metals to allow near band-edge workfunctions. Such metals can shift the threshold voltage (Vt) of a gate stack towards either the n-FET or p-FET band-edge. The threshold voltage (Vt) may be defined as the value at which the n-FET or p-FET device starts to conduct current. One way to achieve this threshold voltage shift in n-FET devices is to use one of many potential n-FET metals. However, less p-FET metal options exist for band-edge workfunctions in p-FET devices. A possible solution includes making the device channel out of a semiconductor with a different band-gap, namely silicon-germanium (SiGe). A silicon-germanium channel may allow achieving near band-edge workfunctions with simpler metallurgical stacks. However, FinFET structures may pose challenges to the growth of a SiGe layer on the fin surface due to size dimensions and other constraints. Another potential solution may be to deposit a material on the silicon fin which can diffuse germanium into the fin and form a thermal SiGe layer on the fin. While these options may work in principle, they can be difficult to implement in practice. Additionally, another problem is that silicon-germanium does not work well for n-FET devices.

### SUMMARY

Improved FinFET channel fabrication processes integrating SiGe channel technology may facilitate advancing the capabilities of current high-k device technology.

According to an embodiment of the present disclosure, a method of forming a semiconductor structure includes forming a first fin in a p-FET device region of a semiconductor substrate and a second fin in an n-FET device region of the semiconductor substrate substantially parallel to the first fin. The first fin and the second fin each include a strained semiconductor material. The second fin is amorphized to form a relaxed fin by implanting ions into the second fin while protecting the first fin.

According to another embodiment of the present disclosure, a method of forming a semiconductor structure includes: forming a silicon-germanium-on-insulator (SGOI) substrate including a base substrate, a buried oxide layer on the base substrate, and a silicon-germanium-on-insulator (SGOI) layer on the buried oxide layer. The SGOI layer is etched to form a first fin in a p-FET device region of the SGOI substrate and a second fin in an n-FET device region of the SGOI substrate. The second fin being substantially parallel to the first fin. The first fin in the p-FET device region is masked and ions are implanted into the second fin to relax the second fin. Then, the first fin in the p-FET device region is unmasked.

According to another embodiment of the present disclosure, a semiconductor structure includes: a first fin located in a p-FET device region of a semiconductor substrate, the first fin including a relaxed semiconductor material and a second fin located in an n-FET device region of the semiconductor substrate substantially parallel to the first fin, the second fin including a strained semiconductor material.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIG. 1 is a cross-sectional view of a silicon-germanium-on-insulator (SGOI) substrate, according to an embodiment of the present disclosure;

FIG. 2 is a cross-sectional view of the SGOI substrate depicting the formation of a mandrel layer on top of a silicon-germanium (SiGe) layer, according to an embodiment of the present disclosure;

FIG. 3 is a cross-sectional view of the SGOI substrate depicting the deposition of a dielectric layer above mandrels, according to an embodiment of the present disclosure;

FIG. 4 is a cross-sectional view of the SGOI substrate depicting the formation of sidewall spacers adjacent to the mandrels, according to an embodiment of the present disclosure;

FIG. 5 is a cross-sectional view of the SGOI substrate depicting the removal of the mandrels, according to an embodiment of the present disclosure;

FIG. 6 is a cross-sectional view of the SGOI substrate depicting etch of the SiGe layer using the sidewall spacers as a mask, according to an embodiment of the present disclosure;

FIG. 7 is a cross-sectional view of the SGOI substrate depicting the formation of a plurality of SiGe fins, according to an embodiment of the present disclosure;

FIG. 8 is a cross-sectional view of the SGOI substrate depicting a p-FET device region of the SGOI substrate being masked, according to an embodiment of the present disclosure;

FIG. 9 is a cross-sectional view of the SGOI substrate depicting an ion implantation process being conducted in the fins located in an n-FET device region of the SGOI substrate, according to an embodiment of the present disclosure; and

FIG. 10 is a cross-sectional view of the SGOI substrate depicting the p-FET device region having strained SiGe fins and the n-FET device region having relaxed SiGe fins, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Exemplary embodiments now will be described more fully herein with reference to the accompanying drawings, in which exemplary embodiments are shown. This invention may, however, be modified in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessary obscuring the presented embodiments.

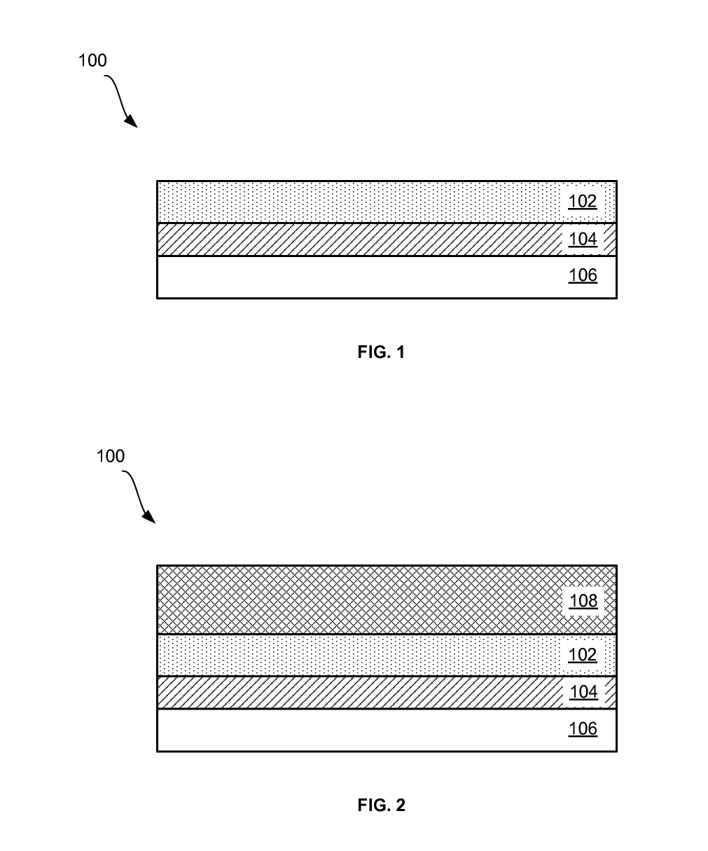

A method of forming a FinFET device having relaxed SiGe fins to optimized threshold voltage in an n-FET device region is described in detail below by referring to the accompanying drawings in FIGS. 1-10, in accordance with an illustrative embodiment of the present disclosure. More specifically, a method of forming a FinFET device on a silicon-germanium-on-insulator substrate that can allow for the functioning of n-FET devices by forming relaxed silicon-germanium fins is described in detail below by referring to the accompanying drawings in FIGS. 8-10. The method may provide a FinFET device having a silicon-germanium channel that can suit p-FET devices and n-FET devices equally. The method requires simpler metallurgical stacks than conventional FinFET fabrication where epitaxial silicon-germanium or carbon-doped silicon layers are grown over the fin surface in order to achieve the desire p-FET or n-FET workfunctions.

Referring to FIG. 1 a silicon-germanium (SiGe)-on-insulator (SGOI) substrate 100 is shown. The SGOI substrate 100 may include a base substrate 106, a buried oxide (BOX) layer 104 formed on top of the base substrate 106, and a SGOI layer or SiGe layer 102 formed on top of the BOX layer 104. The BOX layer 104 isolates the SiGe layer 102 from the base substrate 106.

The base substrate 106 may be made from any of several known semiconductor materials such as, for example, silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. In one embodiment of the present disclosure, the base substrate 106 includes silicon. Typically the base substrate 106 may be about several hundred microns thick. For example, the base substrate 106 may include a thickness ranging from about 0.5 μm to about 75 μm.

The BOX layer 104 may be formed from any of several dielectric materials. Non-limiting examples include, for example, oxides, nitrides and oxynitrides of silicon. The BOX layer 104 may also include oxides, nitrides and oxynitrides of elements other than silicon. In addition, the BOX layer 104 may include crystalline or non-crystalline dielectric material. Moreover, the BOX layer 104 may be formed using any of several methods. Non-limiting examples include ion implantation methods, thermal or plasma oxidation or nitridation methods, chemical vapor deposition methods and physical vapor deposition methods. The BOX layer 104 may include a thickness ranging from about 5 nm to about 200 nm. In one embodiment, the BOX layer 104 may be about 25 nm thick.

The SiGe layer 102 may be formed using any of several methods known in the art. Non-limiting examples include SIMOX (Separation by IMplantation of OXygen), wafer bonding, and ELTRAN® (Epitaxial Layer TRANsfer). Typically, the SiGe layer 102 includes a thickness ranging from about 5 nm to about 100 nm. In one embodiment, the SiGe layer 102 may be about 15 nm thick.

Referring to FIGS. 2-7, the process of forming fins in the SGOI substrate 100 will be described. The fins may be formed by any method known in the art, such as for example: sidewall image transfer (SIT).

FIG. 2 illustrates an intermediate step in the FinFET fabrication process. At this step, a mandrel layer 108 may be deposited on the SGOI substrate 100. The mandrel layer 108 may be made from any of several known semiconductor materials such as, for example, polycrystalline silicon, silicon oxide, silicon nitride, and the like. The mandrel layer 108 may be deposited by any technique known in the art, for example, by chemical vapor deposition (CVD), atomic layer deposition (ALD), physical vapor deposition (PVD), or plasma enhanced chemical vapor deposition (PECVD).

The mandrel layer 108 may preferably include a material that is different enough from the material of the sidewall spacers (described below) so that they may be selectively removed. The particular material chosen may partly depend upon the desired pattern to be formed and the materials selected in subsequent steps discussed below. In one embodiment, the mandrel layer 108 may be formed with a vertical thickness ranging from about 30 nm to about 150 nm.

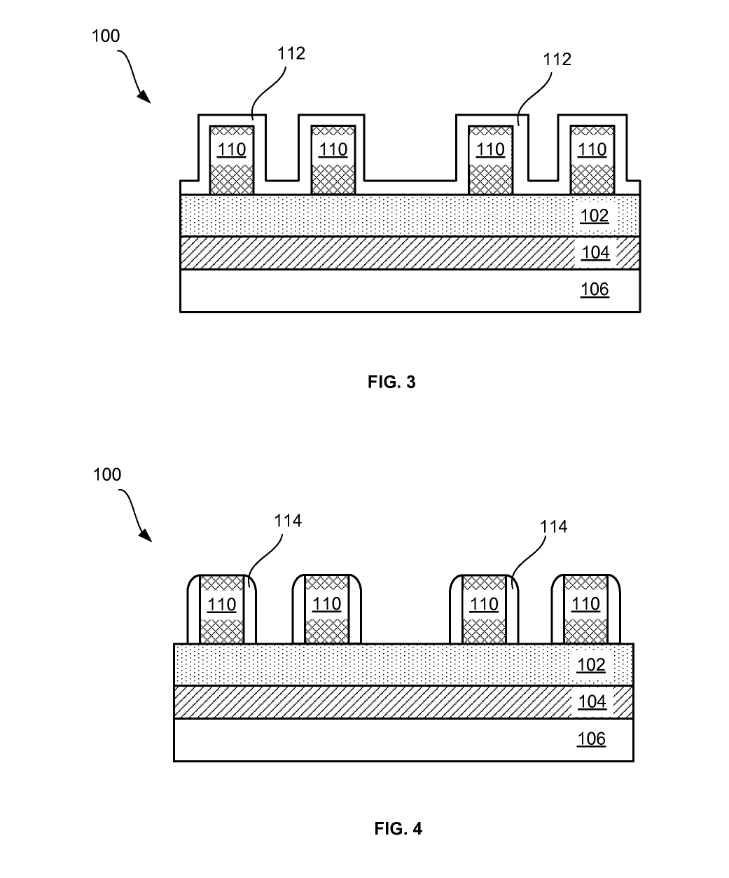

Referring now to FIG. 3, the mandrel layer 108 (shown in FIG. 2) may be lithographically patterned to create mandrels 110. The mandrels 110 can be formed by applying known patterning techniques involving exposing a photo-resist and transferring the exposed pattern of the photo-resist by etching the mandrel layer 108 (shown in FIG. 2). Next, a layer of dielectric material 112 (hereinafter “dielectric layer”) may be conformally deposited directly on top of the SiGe layer 102 and the mandrels 110. In one embodiment, the dielectric layer 112 may include, for example, silicon nitride or silicon oxide. It should be noted that the dielectric layer 112 should include a material that allows the mandrels 110 to be selectively etched in order to avoid further erosion of sidewall spacers 114 (shown in FIG. 4) formed from the dielectric layer 112.

The dielectric layer 112 may be deposited with a conformal deposition technique, using any known atomic layer deposition technique, molecular layer deposition techniques, or any other suitable deposition technique. In one embodiment, the dielectric layer 112 may have a conformal and uniform thickness ranging from about 5 nm to about 50 nm.

Referring to FIG. 4 sidewall spacers 114 may be formed adjacent to the mandrels 110 by subjecting the dielectric layer 112 (FIG. 3) to a directional etching process such as a reactive-ion-etching technique. The directional etching process may remove a portion of the dielectric layer 112 (FIG. 3) from above the SiGe layer 102 and from the top of the mandrels 110. A portion of the dielectric layer 112 may remain along opposite sidewalls of the mandrels 110, forming the sidewall spacers 114. Furthermore, the mandrels 110 and the sidewall spacers 114 should each include materials that would allow the mandrels 110 to be subsequently removed selective to the sidewall spacers 114. Here, it should be noted that the sidewall spacers 114 depicted in FIG. 4 are for illustration purposes and can have a different shape from those shown. The sidewall spacers 114 will subsequently define a fin pattern which ultimately may be transferred into the underlying SiGe layer 102.

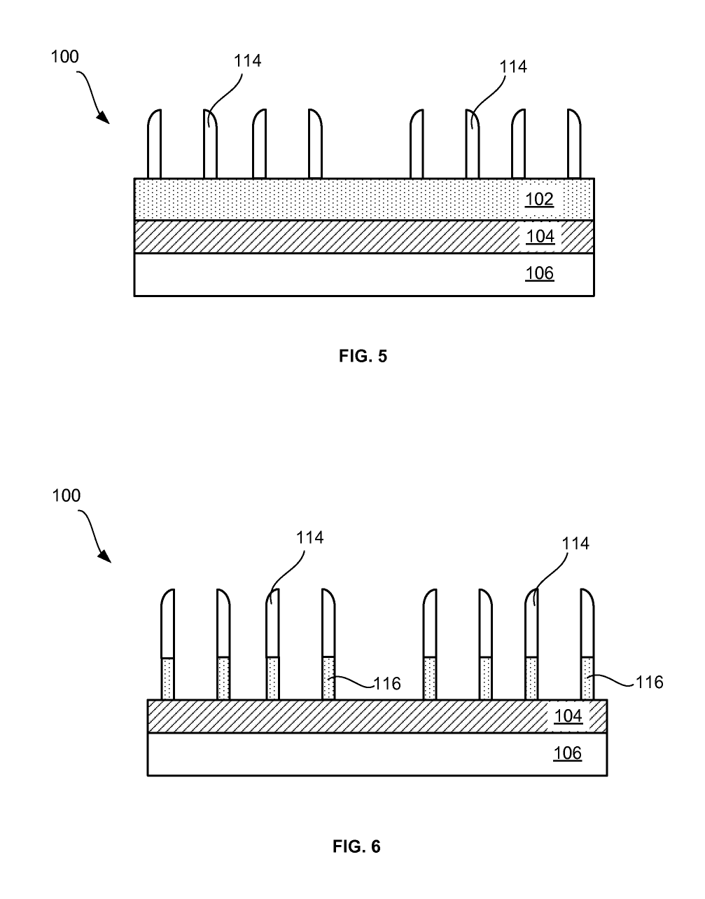

Referring to FIG. 5, the mandrels 110 have been removed selective to the sidewall spacers 114. Removing the mandrels 110 should not compromise the integrity of the sidewall spacers 114. In one embodiment, the mandrels 110 may be removed using a typical standard cleaning technique, including ammonium hydroxide and hydrogen peroxide, in which the sidewall spacers 114 may not be trimmed.

Referring now to FIG. 6, a fin pattern defined by the sidewall spacers 114 may be transferred into the SiGe layer 102 (shown in FIG. 5) to form strained SiGe fins 116. In the present step, the sidewall spacers 114 may function as a mask, and may have high etch selectivity relative to the SiGe layer 102. Next, the SiGe layer 102 may then be etched to a desired depth. The desired depth can depend on the ultimate function of the semiconductor device. A directional etching technique such as a reactive ion etching may be used to etch the SiGe layer 102. In one embodiment, the SiGe layer 102 may be etched with a reactive ion etching technique using a chlorine or a bromine based etchant. Furthermore, the sidewall spacers 114 may be removed in subsequent steps using any suitable removal technique known in the art.

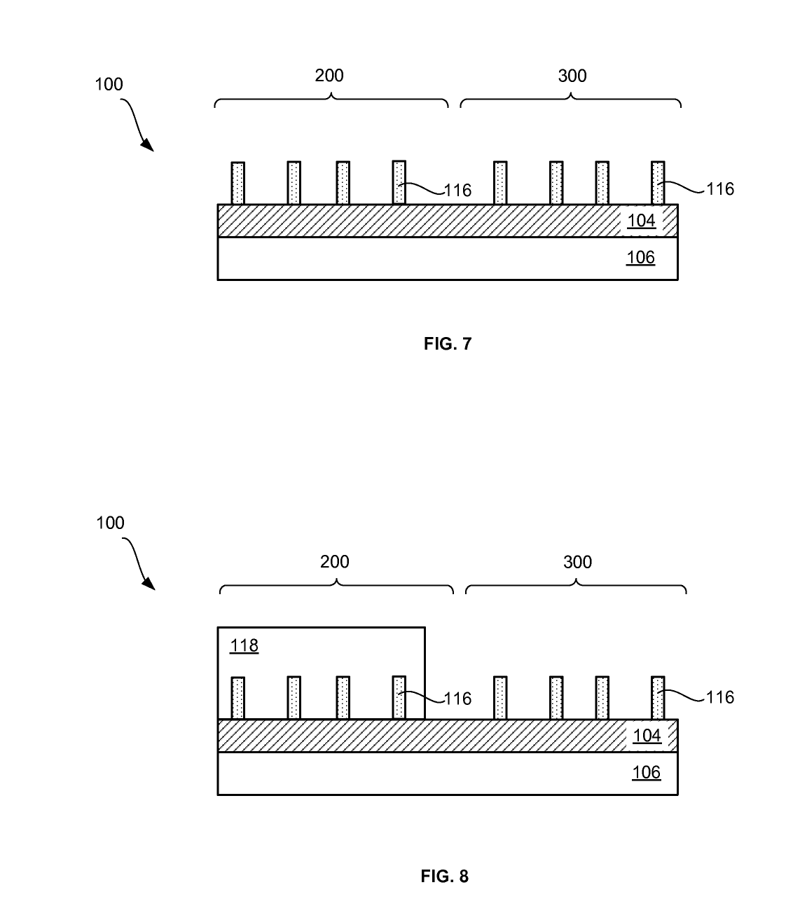

Referring now to FIG. 7, the sidewall spacers 114 shown in FIG. 6 have been selectively removed by means of an etching technique, which can include any suitable wet or dry etching technique. Etching of the sidewall spacers 114 should not compromise the integrity of the strained SiGe fins 116. It should be noted that any number of fins applicable for a specific FinFET design may be manufactured.

With continued reference to FIG. 7, the SGOI substrate 100 having strained silicon-germanium (SiGe) fins 116 may include a p-FET device region 200 and an n-FET device region 300 selected according to a determined FinFET design for the formation of p-FET devices and n-FET devices. The strained SiGe fins 116 may be formed in the p-FET device region 200 and n-FET device region 300. In one embodiment of the present disclosure, the p-FET device region 200 may include the strained SiGe fins 116 required to form a p-FET device while the n-FET device region 300 may include the strained SiGe fins 116 required to form an n-FET device. It is understood that as few as one fin may be included in each region.

At this point of the fabrication process, the strained SiGe fins 116 located in the p-FET device region 200 may provide a strained SiGe channel to the p-FET device to be built in this region thus providing the appropriate p-FET workfunction. However, the strained SiGe fins 116 located in the n-FET device region 300 may not provide the required workfunction for the n-FET device to be built in this region. In order to decrease or relax the strain provided by the strained SiGe fins 116 in the n-FET device region, an ion implantation technique may be conducted in order to change the crystal lattice of the strained SiGe fins 116 to force the silicon-germanium workfunction to closely match the silicon workfunction typically used in n-FET device manufacturing (discussed below).

Referring now to FIG. 8, the p-FET device region 200 may be covered by a hardmask layer 118 in order to protect the strained SiGe fins 116 located within this area of the SGOI substrate 100. The steps involved in masking the p-FET device region 200 are conventional and well known to those skilled in the art. In on embodiment of the present disclosure, the hardmask layer 118 may include silicon nitride and may have a thickness of approximately 15 nm.

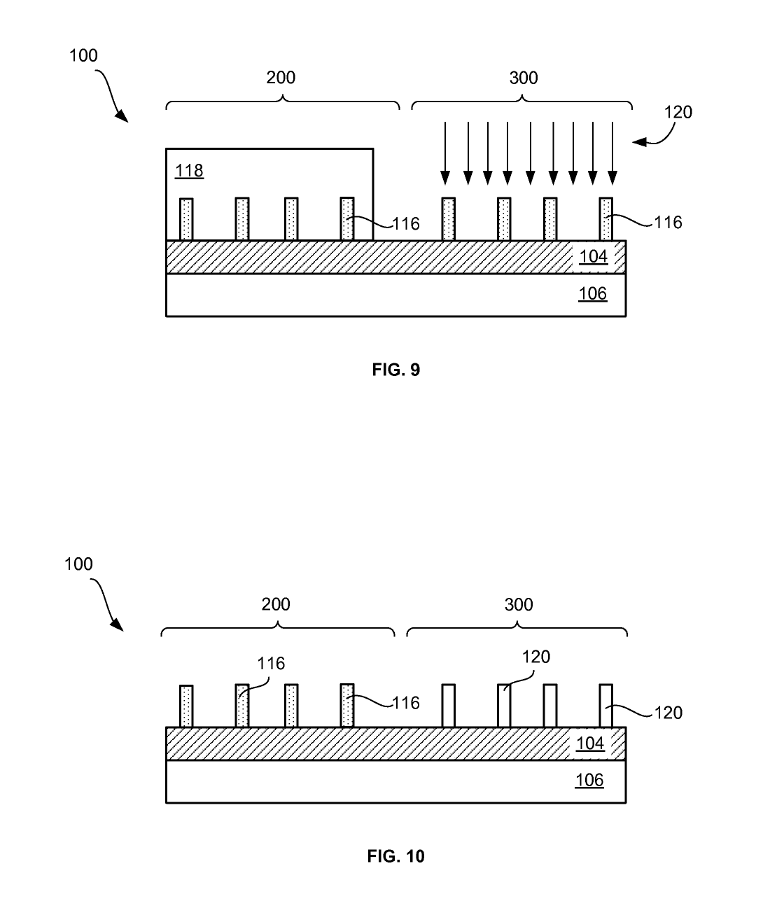

Referring now to FIG. 9, an ion implantation technique may be performed on the uncovered n-FET device region 300 of the SGOI substrate 100. The ion implantation technique, represented by arrows 120, may be used to amorphize the strained SiGe fins 116 of the n-FET device region 300. In an embodiment of the present disclosure, the ion implantation process may include the use of inert amorphizing species such as argon (Ar) or xenon (Xe). In another embodiment of the present disclosure, the ion implantation process may include the use of n-type dopants, such as phosphorus (P) or arsenic (As). The implantation of these atoms may relax the compressively strained SiGe fins 116 in the n-FET device region 300.

According to an embodiment of the present disclosure, the concentration of inert amorphizing species namely argon (Ar) or xenon (Xe) to achieve substantial amorphization of the strained SiGe fins 116 in the n-FET device region 300 may range from about 1×10¹⁴ ions/cm² to about 1×10¹⁵ ions/cm² with a tilt angle ranging from about 0 degrees to about 20 degrees and an implantation energy ranging from about 0.5 keV to about 10 keV.

According to another embodiment of the present disclosure, the dopant concentration of phosphorous (P) to achieve substantial amorphization of the strained SiGe fins 116 in the n-FET device region 300 may range from about 1×10¹⁴ ions/cm² to about 1×10¹⁵ ions/cm² with a tilt angle ranging from about 0 degrees to about 20 degrees and an implantation energy ranging from about 0.5 keV to about 10 keV. Furthermore, the dopant concentration of arsenic (As) to achieve substantial amorphization of the strained SiGe fins 116 in the n-FET device region 300 may range from about 1×10¹⁴ ions/cm² to about 9×10¹⁴ ions/cm² with a tilt angle ranging from about 0 degrees to about 20 degrees and an implantation energy ranging from about 0.5 keV to about 10 keV.

The amorphization of the strained SiGe fins 116 may transform the orderly crystalline structure of the silicon-germanium forming the strained SiGe fins 116 into an amorphous or damaged crystalline structure having different lattice and strain characteristics from those in its original state. The ion implantation process may be conducted with the appropriate dopant concentration and depth so that the entire body of the strained SiGe fins 116 located in the n-FET device region 300 can be substantially amorphized.

After the ion implantation, the directional strain of the strained SiGe fins 116 located in the n-FET device region 300 may be more similar to that of silicon. The implant damage may cause the compressively strained SiGe fins 116 in the n-FET device region 300 to relax forming relaxed SiGe fins 122. The relaxed SiGe fins 122 may now be tensely strained in the n-FET device region 300 which in turn may enhance electron mobility in the n-FET device.

In one embodiment of the present disclosure, some recrystallization may occur within the relaxed SiGe fins 122 during subsequent high thermal processes required in FinFET manufacturing such as for example high thermal annealing processes. However, the recrystallization may not occur to the original state since the crystalline structure of the strained SiGe fins 116 was substantially disrupted during the ion implantation process.

Referring now to FIG. 10, the hardmask layer 118 has been removed from the strained SiGe fins 116 in the p-FET device region 200 by a method known in the art, for example, a reactive ion etching (RIE) technique. The SGOI substrate 100 includes strained SiGe fins 116 located in the p-FET device region 200 and relaxed SiGe fins 120 located in the n-FET device region 300. The strained SiGe fins 116 in the p-FET device region 200 may remain compressively strained, thus improving hole mobility in the p-FET device. The strained SiGe fins 116 and the relaxed SiGe fins 120 may provide the appropriate workfunctions to the p-FET and n-FET devices respectively, in order to optimize voltage threshold and in turn carrier mobility and device performance.

After formation of the relaxed SiGe fins 122, the manufacturing process can continue following typical steps of FinFET device fabrication. Including forming a high-k metal gate using a gate first or a gate last process and the subsequent formation of device contacts.

The steps described above may provide a method for forming FinFET devices having a SiGe channel that may allow for the band-edge threshold voltage required for p-FET devices as well as n-FET devices, using a single material with differing strain characteristics. FinFET devices having a SiGe channel may achieve near band-edge workfunctions with simpler metallurgical stacks than FinFET devices fabricated using traditional straining techniques where epitaxial silicon-germanium or carbon-doped silicon layers may be grown over the surface of silicon fins in order to achieve the desire p-FET or n-FET workfunction. The steps described above may also provide a method for forming FinFET devices that may have enhanced carrier mobility and device performance while decreasing the amount of steps required for achieving the appropriate device workfunction.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method of forming a semiconductor structure, comprising:
forming a first fin in a p-FET device region of a semiconductor substrate and a second fin in an n-FET device region of the semiconductor substrate substantially parallel to the first fin, the first fin and the second fin each comprise a strained semiconductor material; and
amorphizing the second fin to form a relaxed fin by implanting ions into the second fin while protecting the first fin.

2. The method of claim 1, wherein forming the first fin in the p-FET device region of the semiconductor substrate and the second fin in the n-FET device region of the semiconductor substrate comprises:
forming a silicon-germanium-on-insulator substrate including a base substrate, a buried oxide layer on the base substrate, and a silicon-germanium-on-insulator (SGOI) layer on the buried oxide layer; and
etching the SGOI layer to form the first fin and the second fin.

3. The method of claim 2, wherein etching the SGOI layer comprises:
forming sidewall spacers above the SGOI layer and along opposite sidewalls of a mandrel;
removing the mandrel selective to the sidewall spacers and SGOI layer; and
transferring a fin pattern defined by the sidewall spacers into the SGOI layer to form the first fin in the p-FET device region and the second fin in the n-FET device region.

4. The method of claim 1, wherein forming the first fin in the p-FET device region of the semiconductor substrate and the second fin in the n-FET device region of the semiconductor substrate comprises forming silicon-germanium fins having a lattice constant greater than the lattice constant of silicon.

5. The method of claim 1, wherein amorphizing the second fin to form a relaxed fin by implanting ions into the second fin while protecting the first fin comprises implanting inert amorphizing species or n-type dopants into the second fin.

6. The method of claim 5, wherein implanting the inert amorphizing species comprises implanting argon or xenon.

7. The method of claim 5, wherein implanting the n-type dopants comprises implanting arsenic or phosphorus.

8. The method of claim 1, wherein amorphizing the second fin to form a relaxed fin by implanting ions into the second fin while protecting the first fin comprises a strain of the lattice of the relaxed fin being smaller than a strain of the lattice of the second fin prior to amorphizing the second fin.

9. The method of claim 8, wherein the strain of the lattice of the relaxed fin is substantially similar to that of silicon.

10. A method of forming a semiconductor device, the method comprising:
forming a silicon-germanium-on-insulator (SGOI) substrate including a base substrate, a buried oxide layer on the base substrate, and a silicon-germanium-on-insulator (SGOI) layer on the buried oxide layer;
etching the SGOI layer to form a first fin in a p-FET device region of the SGOI substrate and a second fin in a n-FET device region of the SGOI substrate, the second fin being substantially parallel to the first fin;
masking the first fin in the p-FET device region;
implanting ions into the second fin to relax the second fin; and
unmasking the first fin in the p-FET device region.

11. The method of claim 10, wherein etching the SGOI layer comprises:
forming sidewall spacers above the SGOI layer and along opposite sidewalls of a mandrel;
removing the mandrel selective to the sidewall spacers and SGOI layer; and
transferring a fin pattern defined by the sidewall spacers into the SGOI layer to form the first fin in the p-FET device region and the second fin in the n-FET device region.

12. The method of claim 10, wherein masking the first fin comprises depositing a hardmask layer on top of the first fin to protect the first fin in the p-FET device region during implantation of the second fin in the n-FET device region.

13. The method of claim 10, wherein implanting ions into the second fin comprises implanting inert amorphizing species or n-type dopants into the second fin to amorphize a lattice structure of the second fin.

14. The method of claim 13, wherein implanting the inert amorphizing species comprises implanting argon or xenon.

15. The method of claim 13, wherein implanting the n-type dopants comprises implanting arsenic or phosphorus.

16. The method of claim 10, wherein implanting ions into the second fin to relax the second fin comprises a strain of the lattice of the relaxed fin being smaller than a strain of the lattice of the second fin prior to implanting the ions on the second fin.

17. The method of claim 16, wherein the strain of the lattice of the relaxed fin is substantially similar to that of silicon.

18. A semiconductor structure comprising:
a first fin located in a p-FET device region of a semiconductor substrate, wherein the first fin comprises a relaxed semiconductor material; and
a second fin located in an n-FET device region of the semiconductor substrate substantially parallel to the first fin, wherein the second fin comprises a strained semiconductor material.

19. The structure of claim 18, wherein the second fin comprises relaxed silicon-germanium fins having an amorphized crystalline structure with similar lattice strain to silicon.

20. The structure of claim 18, wherein the semiconductor substrate comprises a silicon-germanium on insulator substrate.
